(19) United States
(12) Patent Application Publication
(10) Pub. No.: US 2015/0187795 A1
(43) Pub. Date: Jul. 2, 2015

(54) SEMICONDUCTOR DEVICE AND METHOD FOR MANUFACTURING SEMICONDUCTOR DEVICE

(71) Applicant: TOYOTA JIDOSHA KABUSHIKI KAISHA, Toyota-shi (JP)

(72) Inventor: Satoru Kameyama, Toyota-shi (JP)

(21) Appl. No.: 14/575,138

(22) Filed: Dec. 18, 2014

(30) Foreign Application Priority Data
Dec. 26, 2013 (JP) 2013-269262

(51) Int. Cl. H01L 27/12; H01L 29/06; H01L 27/06; H01L 21/265; H01L 29/66; H01L 29/739; H01L 21/02

(52) U.S. Cl. CPC H01L 27/1203; H01L 29/7394; H01L 29/0696; H01L 21/02636; H01L 21/0242; H01L 21/265; H01L 29/7397; H01L 29/66348; H01L 27/0635

(57) ABSTRACT

An insulated gate type switching element which can control a gate potential appropriately in accordance with a potential of a rear surface electrode is provided. A semiconductor device has a semiconductor substrate, a front surface electrode on a front surface of the semiconductor substrate, and a rear surface electrode on a rear surface thereof. The semiconductor substrate has an element region having the insulated gate type switching element which switches current flowing from the front surface electrode to the rear surface electrode and a peripheral region between the element region and an edge surface of the semiconductor substrate. A detection electrode is located on a part of the front surface and an insulating layer is located on a part of the front surface of the semiconductor substrate in the peripheral region. A diode is located on the insulating layer, a cathode of which is connected to the detection electrode.

### CROSS-REFERENCE TO RELATED APPLICATION

This application claims priority to Japanese Patent Application No. 2013-269262 filed on Dec. 26, 2013, the contents of which are hereby incorporated by reference into the present application.

### TECHNICAL FIELD

A technology disclosed in this specification relates to a semiconductor device.

### DESCRIPTION OF RELATED ART

Japanese Patent Application Publication No. 2011-187880 discloses a semiconductor device having an IGBT configured to switch current between a front surface electrode and a rear surface electrode. In this semiconductor device, a chip terminal region is formed in a semiconductor substrate and between a region in which the IGBT is formed and an edge surface of the semiconductor substrate. A channel stopper electrode is formed on a front surface of the semiconductor substrate in the chip terminal region.

### BRIEF SUMMARY

In an insulated gate type switching type element described in Japanese Patent Application Publication No. 2011-187880, there is a case in which a gate potential is controlled on the basis of a potential of the rear surface electrode. In this case, the gate potential needs to be controlled appropriately in accordance with the potential of the rear surface electrode.

In the semiconductor device in Japanese Patent Application Publication No. 2011-187880, the channel stopper electrode is formed in the chip terminal region. In the insulated gate type switching element configured to switch the current between the front surface electrode and the rear surface electrode as in Japanese Patent Application Publication No. 2011-187880, a potential in a region in the vicinity of the edge surface of the semiconductor substrate is substantially equal to the potential of the rear surface electrode. Therefore, the potential of the rear surface electrode can be detected by the channel stopper electrode formed in the chip terminal region. Here, the potential of the rear surface electrode with respect to the front surface electrode is a low potential while the switching element is ON, but it becomes a high potential while the switching element is OFF. That is, a variation range in the potential of the rear surface electrode is extremely large. Thus, if a signal obtained by the channel stopper electrode is to be inputted into a detection circuit (IC or the like) without any adjustment, the detection circuit having an extremely high withstand voltage needs to be prepared.

In order to cope with the above problem, the applicant of the present application proposed a potential detection circuit having a level shift circuit in Japanese Patent Application No. 2013-094312. This potential detection circuit includes a diode connected to a collector of an IGBT (a diode for a level shift circuit, hereinafter referred to as a detection diode). A potential of an anode of the detection diode changes in accordance with a collector potential of the IGBT. At this occasion, the variation range in the potential of the anode of the detection diode is considerably smaller than the variation range in the collector potential of the IGBT. Therefore, the detection circuit having a relatively low withstand voltage can be used by inputting the potential of the anode of the detection diode to the detection circuit.

However, the above-described detection diode used for the level shift circuit is provided on a circuit substrate (i.e., a printed circuit board or the like) separately from the insulated gate type switching element. Thus, there was a problem that this arrangement increases the circuit substrate size. Moreover, since the detection diode is arranged in a position apart from the collector, there was a problem that the potential of the collector and the potential of the diode become different such that accurate detection of the collector potential becomes difficult. Thus, in this description, the following semiconductor device is proposed.

A semiconductor device disclosed herein comprises a semiconductor substrate, a front surface electrode located on a front surface of the semiconductor substrate, and a rear surface electrode located on a rear surface of the semiconductor substrate. The semiconductor substrate comprises: an element region comprising an insulated gate type switching element configured to switch current which flows from the front surface electrode to the rear surface electrode; and a peripheral region located between the element region and an edge surface of the semiconductor substrate. A detection electrode is located on a part of the front surface of the semiconductor substrate in the peripheral region. An insulating layer is located on a part of the front surface of the semiconductor substrate in the peripheral region. A diode is located on the insulating layer, a cathode of the diode being connected to the detection electrode.

In this semiconductor device, the detection electrode is formed on a part of the surface of the semiconductor substrate in the peripheral region. The potential of the rear surface electrode can be accurately detected according to the detection electrode formed in the peripheral region. Moreover in this semiconductor device, a diode having the cathode connected to the detection electrode is arranged on the insulating layer in the peripheral region. Therefore, a level shift circuit can be configured using this diode. Moreover, this diode is arranged on the insulating layer on the front surface of the semiconductor substrate. Thus, there is no need to provide the detection diode on the circuit substrate. Therefore, this semiconductor device can make the circuit substrate smaller. Moreover, since the detection diode can be arranged close to the semiconductor substrate, the potential of the rear surface electrode can be accurately detected.

### BRIEF DESCRIPTION OF DRAWINGS

FIG. 1 is a plan view of a semiconductor device 10;

FIG. 2 is a longitudinal sectional view along II-II line in FIG. 1;

FIG. 3 is a longitudinal sectional view along III-III line in FIG. 1;

FIG. 4 is a circuit diagram of an inverter circuit using the semiconductor device 10;

FIG. 5 is a plan view of a semiconductor device 100;

FIG. 6 is a longitudinal sectional view along VI-VI line in FIG. 5; and

FIG. 7 is a longitudinal sectional view along VII-VII line in FIG. 5.

### DETAILED DESCRIPTION

### Embodiment 1

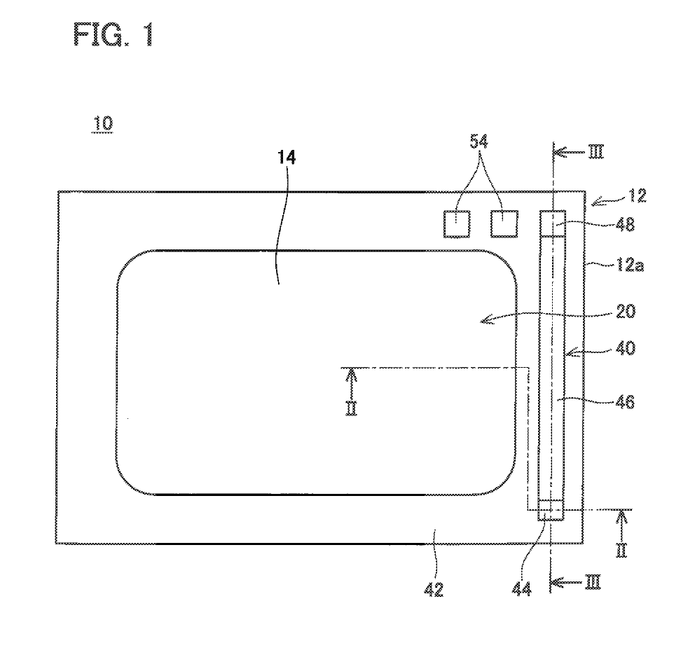

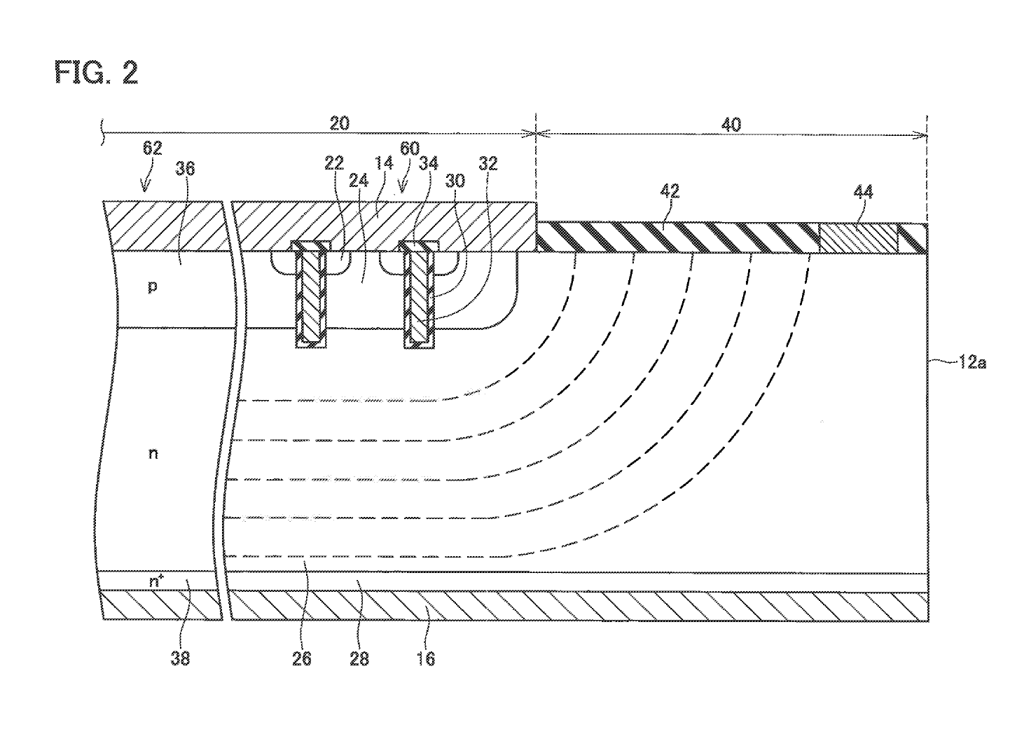

A semiconductor device 10 illustrated in FIGS. 1 and 2 has a semiconductor substrate 12. The semiconductor substrate 12 has an element region 20 in which an IGBT is formed and a peripheral region 40 located between the element region 20 and an edge surface (peripheral surface) 12a of the semiconductor substrate 12. An emitter electrode 14 is formed on a front surface of the semiconductor substrate 12 in the element region 20. A collector electrode 16 is formed on a rear surface of the semiconductor substrate 12.

An emitter region 22, a body region 24, a drift region 26 and a collector region 28 are formed inside the semiconductor substrate 12 in the element region 20. The emitter region 22 is of n-type and is connected to the emitter electrode 14. The body region 24 is of p-type and is formed on a lateral side and a lower side of the emitter region 22. The body region 24 is connected to the emitter electrode 14. The drift region 26 is of n-type and is formed on a lower side of the body region 24. The drift region 26 is separated from the emitter region 22 by the body region 24. The collector region 28 is of p-type and is formed on a lower side of the drift region 26. The collector region 28 is separated from the body region 24 by the drift region 26. The collector region 28 is connected to a collector electrode 16. A plurality of trenches is formed on a front surface of the semiconductor substrate 12 in the element region 20. Each of the trenches penetrates the emitter region 22 and the body region 24 to reach the drift region 26. A gate insulating film 30 and a gate electrode 32 are formed in each of the trenches. The gate insulating film 30 covers an inner surface of the trench. The gate electrode 32 is insulated from the semiconductor substrate 12 by the gate insulating film 30. The gate electrode 32 is faced via the gate insulating film 30 with the body region 24 located between the emitter region 22 and the drift region 26. An upper surface of the gate electrode 32 is covered by an insulating layer 34. The gate electrode 32 is insulated from the emitter electrode 14 by the insulating layer 34. An IGBT 60 is formed of the emitter region 22, the body region 24, the drift region 26, the collector region 28, the gate insulating film 30 and the gate electrode 32.

Moreover, an anode region 36 and a cathode region 38 are formed inside the semiconductor substrate 12 in the element region 20. The anode region 36 is of p-type and is connected to the emitter electrode 14. The above-described drift region 26 is formed on a lower side of the anode region 36. The cathode region 38 is formed on a lower side of the drift region 26. The cathode region 38 is of n-type and is connected to the collector electrode 16. N-type impurity concentration of the cathode region 38 is higher than the n-type impurity concentration of the drift region 26. A freewheeling diode 62 is formed of the anode region 36, the drift region 26 and the cathode region 38.

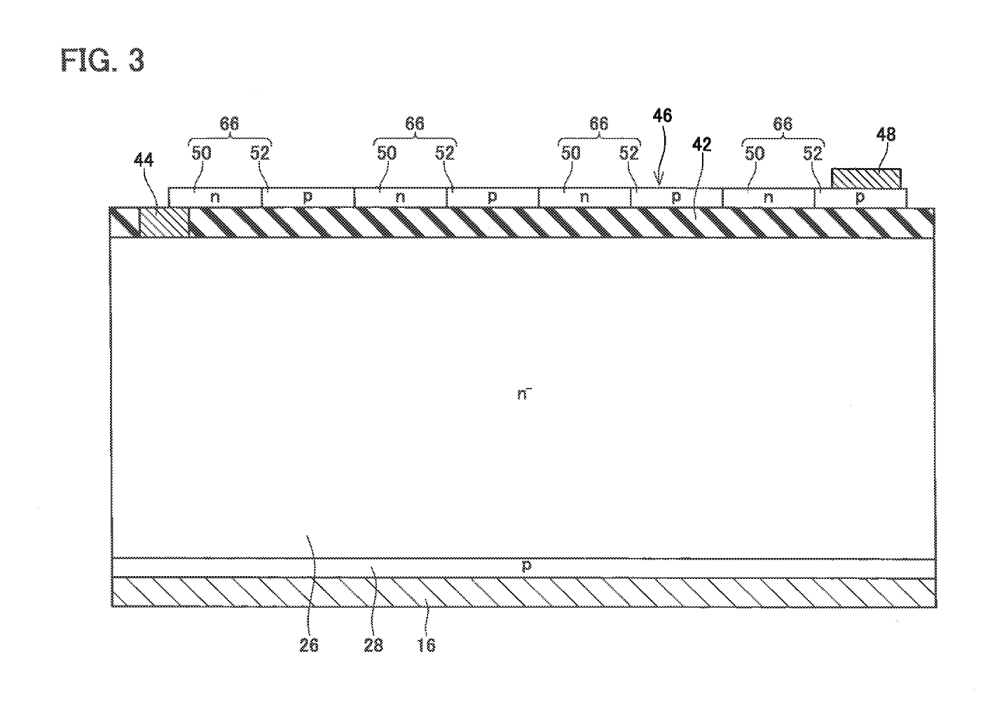

The drift region 26 and the collector region 28 extend into the peripheral region 40. Moreover, most of the front surface of the semiconductor substrate 12 in the peripheral region 40 is covered by an insulating layer 42. As illustrated in FIG. 2, an opening is provided in the insulating layer 42 close to the edge surface 12a of the semiconductor substrate 12 and a detection electrode 44 is formed in the opening. The detection electrode 44 is connected to the drift region 26. As illustrated in FIGS. 1 and 3, a semiconductor layer 46 and an anode electrode pad 48 are formed on a part of the insulating layer 42. One end of the semiconductor layer 46 is connected to the detection electrode 44. The other end of the semiconductor layer 46 is connected to the anode electrode pad 48. In the semiconductor layer 46, n-type cathode regions 50 and p-type anode regions 52 are alternately and repetitiously formed along a direction from the detection electrode 44 toward the anode electrode pad 48. Thus, a plurality of diodes 66 is formed in the semiconductor layer 46. Each of the diodes 66 is connected in series between the detection electrode 44 and the anode electrode pad 48. Each of the diodes 66 has a cathode on a detection electrode 44 side and an anode on an anode electrode pad 48 side. The anode electrode pad 48 is connected to an external wiring by a wire (not shown).

Moreover, as illustrated in FIG. 1, a plurality of electrode pads 54 is formed on the front surface of the semiconductor device 10 in the peripheral region 40. Though this is not shown, the electrode pad 54 is connected to either of the electrodes (the gate electrode 32 for example) of the IGBT 60 or the freewheeling diode 62. The anode electrode pad 48 is arranged in a position adjacent to one of the electrode pads 54. In other words, no other electrode pad is arranged between the anode electrode pad 48 and the one electrode pad 54.

When a potential of the emitter electrode 14 becomes higher than a potential of the collector electrode 16, the freewheeling diode 62 is turned on and an electric current flows from the emitter electrode 14 toward the collector electrode 16. When the potential of the collector electrode 16 becomes higher than the potential of the emitter electrode 14 and a potential at a threshold value or more is applied to the gate electrode 32, the IGBT 60 is turned on. Thus, the electric current flows from the collector electrode 16 toward the emitter electrode 14. When the potential of the collector electrode 16 becomes higher than the potential of the emitter electrode 14 and the potential of the gate electrode 32 becomes less than the threshold value, the IGBT 60 is turned off. When the IGBT 60 is turned off, a depletion layer extends from a boundary between the body region 24 and the drift region 26 into the drift region 26. As a result, a potential difference is caused in the drift region 26. At this time, the potential is distributed in the drift region 26 as indicated by dot lines (equipotential lines) in FIG. 2. Since the potential is distributed as mentioned above, the potential of the detection electrode 44 becomes substantially equal to the potential of the collector electrode 16. The potential of the collector electrode 16 can therefore be detected by the detection electrode 44.

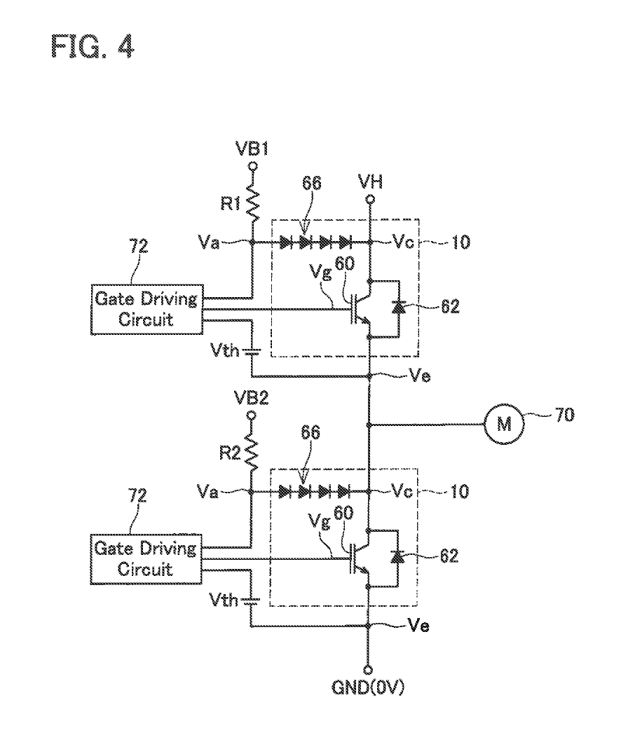

FIG. 4 shows a circuit in which the semiconductor device 10 is incorporated. The circuit in FIG. 4 is a part (one phase) of a three-phase inverter circuit for driving a motor 70. The circuit in FIG. 4 uses two above-described semiconductor devices 10. One semiconductor device 10 is used for an upper arm while the other one semiconductor device 10 is used for a lower arm. Each of the semiconductor devices 10 has the IGBT 60 and the freewheeling diode 62 connected in reversely parallel to the IGBT 60. Moreover, the above-described diode 66 is connected to the collector potential via the detection electrode 44 and thus in FIG. 4 the diode 66 is connected to a collector electrode of the IGBT 60. The collector electrode of the IGBT 60 in the upper arm is connected to a high potential VH (approximately 1200 V). An emitter electrode of the IGBT 60 in the upper arm is connected to the motor 70 and a collector electrode of the IGBT 60 in the lower arm. An emitter electrode of the IGBT 60 in the lower arm is connected to a ground (i.e., 0 V). An anode electrode of the diode 66 in the upper arm is connected to a potential VB1 via a resistor R1. An anode electrode of the diode 66 in the lower arm is connected to a potential VB2 via a resistor R2. Moreover, a gate driving circuit 72 is connected to the anode electrode of each of the diodes 66. Further, a potential higher than an emitter potential of the corresponding IGBT 60 only by a threshold potential Vth is inputted to the gate driving circuit 72 The gate driving circuit 72 is connected to a gate electrode of the corresponding IGBT 60. The gate driving circuit 72 controls the IGBT 60 by controlling the gate potential of the corresponding IGBT 60. Since a general switching control of the IGBT in the three-phase inverter circuit is widely known, only a featured control of the gate driving circuit 72 will be explained below.

The gate driving circuit 72 controls a gate potential Vg such that, the IGBT 60 is not turned on when a collector potential Vc of the corresponding IGBT 60 is low. Since operations of the circuits in the upper arm and the lower arm are substantially equal to each other, the operation of the circuit in the lower arm will only be explained below. If the IGBT 60 is OFF and the collector potential Vc of the IGBT 60 is higher than an emitter potential Ve (i.e. 0 V), the freewheeling diode 62 is OFF. In this case, the collector potential Vc of the IGBT 60 is an extremely high potential (approximately 1200 V, for example). In this case, since the potential VB2 is approximately 12 V and is lower than the collector potential Vc, a backward voltage is applied to the diode 66. Therefore, the diode 66 is OFF. Thus, an anode potential Va of the diode 66 becomes equal to the potential VB2 and the potential VB2 is inputted as the anode potential Va into the gate driving circuit 72. The gate driving circuit 72 compares the anode potential Va (i.e. the potential VB2) with the threshold potential Vth. The threshold potential Vth is set to a value lower than the potential VB2. Therefore, the gate driving circuit 72 determines that the anode potential Va is higher than the threshold potential Vth. In this case (i.e. when the collector potential Vc is higher), the gate driving circuit 72 controls the gate potential of the IGBT 60 such that the IGBT 60 is switched in accordance with an external signal (a PWM signal, for example).

If the IGBT 60 is OFF and the collector potential Vc of the IGBT 60 is lower than the emitter potential Ve (i.e. 0 V), the freewheeling diode 62 is ON. In this case, since the collector potential Vc of the IGBT 60 is lower than 0 V, a forward voltage is applied to the diode 66. Thus, the diode 66 is turned on and the anode potential Va of the diode 66 becomes a potential substantially equal to 0 V. Therefore, the potential substantially equal to 0 V is inputted as the anode potential Va into the gate driving circuit 72. The gate driving circuit 72 determines that the inputted anode potential Va (i.e. the potential substantially equal to 0 V) is lower than the threshold potential Vth. In this case (i.e. when the collector potential Vc is lower), the gate driving circuit 72 controls the gate voltage of the IGBT 60 such that the IGBT 60 is turned off regardless of the external signal. This can prevent the IGBT 60 from being turned on at the same time as the freewheeling diode 62.

In the circuit in FIG. 4, even though the variation range in the collector potential Vc is large, the variation range in the anode potential Va inputted into the gate driving circuit 72 is small. As described above, the level shift circuit for outputting the anode potential Va lower than the collector potential Vc is configured by the diode 66, the resistor R1 and so on. Since the anode potential Va having a small variation range is inputted into the gate driving circuit 72 as described above, the gate driving circuit 72 with a moderate withstand voltage characteristic can be used.

Moreover, in the above-described semiconductor device 10, there is no need to provide a diode for the level shift circuit separately from the semiconductor device 10 since the diode 66 is formed on the semiconductor substrate 12. Therefore, there is no need to mount the diode for the level shift circuit on the circuit board so that the size of the circuit board can be made smaller.

Moreover, in the above-described semiconductor device 10, the detection electrode 44 for detecting a collector potential is formed on the semiconductor substrate 12 and also the diode 66 connected to the detection electrode 44 is formed on the semiconductor substrate 12. Thus, a wiring distance from the diode 66 to the collector electrode 16 is so extremely short that the collector potential can be detected with high accuracy. That is, if the wiring distance from the collector electrode 16 to the diode 66 is long, detection accuracy of the collector potential is lowered by influences of parasitic capacitance, parasitic inductance and resistance of the wiring. Contrary to this, in the semiconductor device 10 of this embodiment, the collector potential can be detected with high accuracy because the wiring distance from the diode 66 to the collector electrode 16 is short.

Moreover, in the above-described semiconductor device 10, the anode electrode pad 48 of the diode 66 is arranged at the position adjacent to the electrode pad 54. The arrangement of the anode electrode pad 48 as described above facilitates wire routing when the wire is bonded to the anode electrode pad 48 and the electrode pad 54.

It should be noted that the above-described semiconductor device 10 can be manufactured by a following method. First, the IGBT 60 and the freewheeling diode 62 are formed in the semiconductor substrate 12. Subsequently, the insulating layer 42 is formed on the peripheral region 40 of the semiconductor substrate 12. Subsequently, the insulating layer 42 is partially etched so as to form the opening for the detection electrode 44. Subsequently, the detection electrode 44 is formed in the formed opening. Subsequently, the semiconductor layer 46 is formed by forming a polysilicon layer or growing an epitaxial layer on the insulating layer 42. Subsequently, a cathode region 50 and an anode region 52 are formed by selectively implanting p-type impurities and n-type impurities into the semiconductor layer 46. Subsequently, the anode electrode pad 48 is formed on the semiconductor layer 46. After these processes, the semiconductor device 10 is completed by forming other necessary structures. It should be noted that an order of each of the processes in the above-described manufacturing method may be changed as necessary.

The semiconductor device 10 of the above-described embodiment has the plurality of the diodes 66 connected in series for the level shift circuit. However, it should be appreciated that the number of the diodes 66 may be changed in accordance with a required withstand voltage and alternatively may be one.

### Embodiment 2

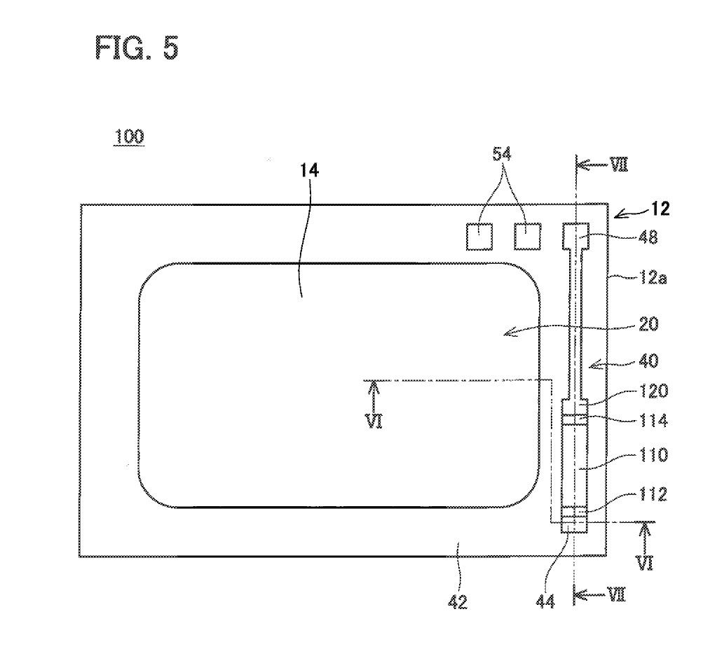

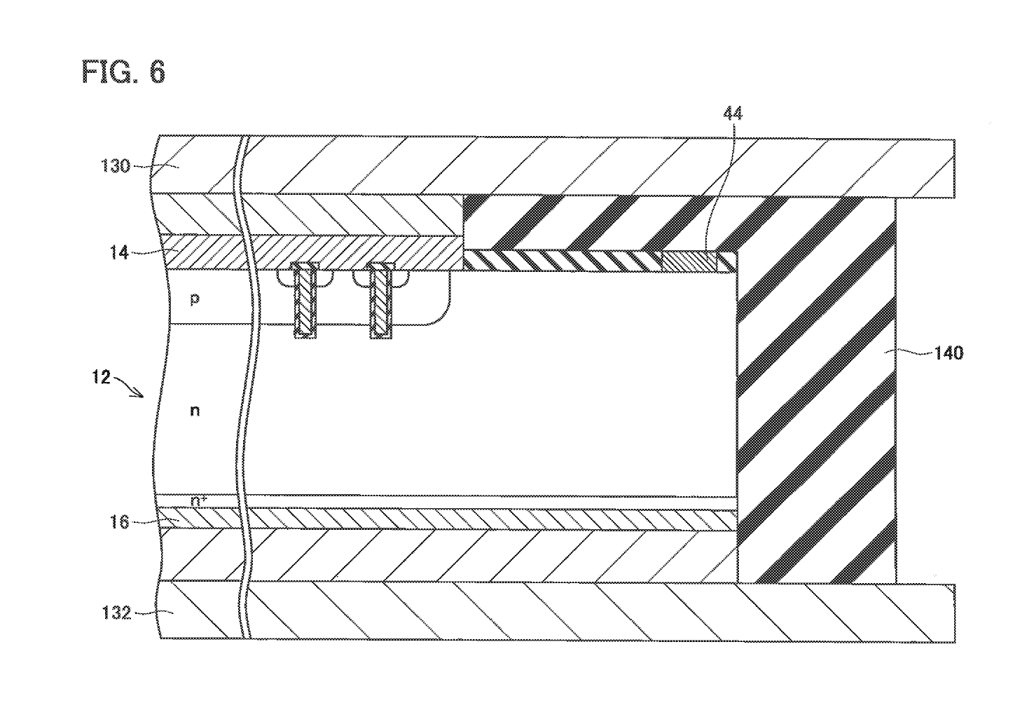

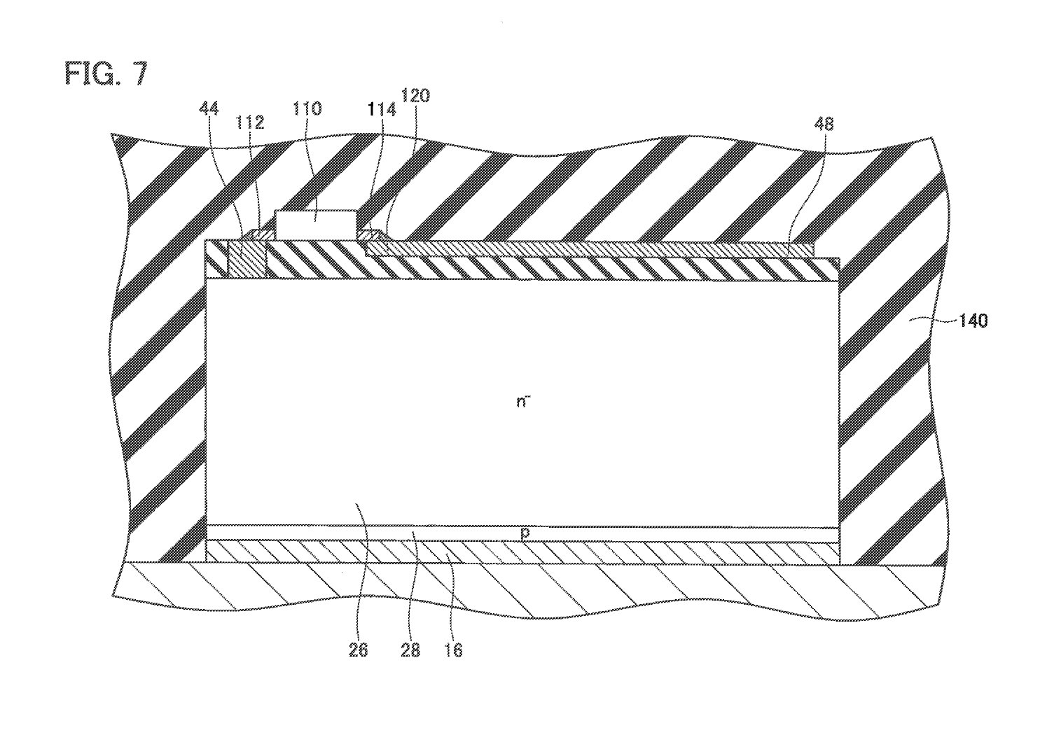

Subsequently, a semiconductor device 100 of Embodiment 2 will be explained. The semiconductor device 100 of Embodiment 2 is equal to the semiconductor device 10 in Embodiment 1 except the configuration of the diode for the level shift circuit. As illustrated in FIGS. 5 to 7, in the semiconductor device 100 of Embodiment 2, a diode 110 of a discrete component (a component packaged for soldering) is connected by soldering to a detection electrode 44. A cathode electrode 112 of the diode 110 is connected to the detection electrode 44 by soldering. An anode electrode 114 of the diode 110 is connected by soldering to an electrode pad 120 provided on an insulating layer 42. The electrode pad 120 is insulated by the insulating layer 42 from a semiconductor substrate 12. The electrode pad 120 is connected to an anode electrode pad 48 by wiring provided on the insulating layer 42. The anode electrode pad 48 is connected to external wiring by a wire (not shown). As illustrated in FIG. 6, an emitter electrode 14 is joined to an electrode plate 130 by solder and a metal block or the like. A collector electrode 16 is connected to an electrode plate 132 by solder and a metal block or the like. A resin layer 140 is formed between the electrode plate 130 and the electrode plate 132. The resin layer 140 covers entirely the semiconductor substrate 12 and the diode 110.

The semiconductor device 100 of Embodiment 2 can operate similarly to the semiconductor device 10 of Embodiment 1 as well. Moreover, in the semiconductor device 100 of Embodiment 2, a solder joining portion connecting the diode 110 and the semiconductor substrate 12 is covered by the resin layer 140. This configuration improves reliability of the solder joining portion.

It should be noted that other type of insulated gate type switching element such as a MOSFET may also be formed although the IGBT is formed on the semiconductor substrate in the semiconductor device of the above-described Embodiments 1 and 2.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

Some aspects of the teaching disclosed herein will further be described. The semiconductor device disclosed herein may further comprise a semiconductor layer and an anode electrode arranged on the insulating layer. The semiconductor layer may comprise an n-type cathode layer connected to the detection electrode and a p-type anode layer in contact with the cathode layer. Moreover, the anode electrode may be connected to the anode layer.

In this case, an electrode pad may be arranged on a surface of the semiconductor device and the anode electrode may be arranged in a position adjacent to the electrode pad.

In addition, the diode may be a discrete type diode comprising a cathode terminal connected to the detection electrode. The diode and the semiconductor substrate may be covered with resin.

1. A semiconductor device, comprising:
a semiconductor substrate;
a front surface electrode located on a front surface of the semiconductor substrate; and
a rear surface electrode located on a rear surface of the semiconductor substrate;
wherein the semiconductor substrate comprises:
an element region comprising an insulated gate type switching element configured to switch current which flows from the front surface electrode to the rear surface electrode, and
a peripheral region located between the element region and an edge surface of the semiconductor substrate,
the semiconductor device further comprising:
a detection electrode located on a part of the front surface of the semiconductor substrate in the peripheral region;
an insulating layer located on a part of the front surface of the semiconductor substrate in the peripheral region; and
a diode located on the insulating layer, a cathode of the diode being connected to the detection electrode.

2. A semiconductor device of claim 1, further comprising:
a semiconductor layer and an anode electrode located on the insulating layer,
wherein the semiconductor layer comprises a cathode layer and an anode layer,
the cathode layer is of n-type and connected to the detection electrode,
the anode layer is of p-type and in contact with the cathode layer, and
the anode electrode is connected to the anode layer.

3. A semiconductor device of claim 2, further comprising:
an electrode pad located on a surface of the semiconductor device,
wherein the anode electrode is located in a position adjacent to the electrode pad.

4. A semiconductor device of claim 1, wherein
the diode is a discrete type diode comprising a cathode terminal connected to the detection electrode, and
the diode and the semiconductor substrate are covered with resin.

5. A method for manufacturing the semiconductor device of claim 1, the method comprising:
growing a semiconductor layer on an insulating layer located on a front surface of a semiconductor substrate;
implanting n-type impurities into the semiconductor layer so as to form an n-type cathode layer connected to the detection electrode; and
implanting p-type impurities into the semiconductor layer so as to from a p-type anode layer in contact with the cathode layer.
